(19) United States
(12) Patent Application Publication
(10) Pub. No.: US 2025/0048692 A1
(43) Pub. Date: Feb. 6, 2025

(54) POWER SEMICONDUCTOR DEVICE AND CELL DATA GENERATING SYSTEM

(71) Applicant: MINEBEA POWER SEMICONDUCTOR DEVICE INC., Hitachi-shi (JP)

(72) Inventors: Takeru SUTO, Tokyo (JP); Haruka SHIMIZU, Tokyo (JP); Tomoka SUEMATSU, Tokyo (JP); Keisuke KOBAYASHI, Tokyo (JP)

(21) Appl. No.: 18/784,537

(22) Filed: Jul. 25, 2024

(30) Foreign Application Priority Data
Jul. 31, 2023 (JP) 2023-124235

(51) Int. Cl. H01L 29/06; H01L 29/78

(52) U.S. Cl. CPC H01L 29/0696; H01L 29/0607; H01L 29/7832

(57) ABSTRACT

A performance of a power semiconductor device is improved. A power semiconductor device including unit cells UR and UL cyclically arranged in an X direction and a Y direction perpendicular to each other and a plurality of end cells is used. The unit cells UR and UL are alternately arranged in the X direction, the plurality of end cells include an X-end cell XL, Y-end cells YR and YL, an XY-end cell XY1L, and an XY-end cell XY2L for an optional region, each number of arrangement cycles of the unit cells UR and UL in the Y direction changes depending on repetition cycle coordinates in the X direction, each of the cyclically-arranged unit cells UR and UL is adjacent to any of the plurality of end cells at an endmost portion of arrangement cycle in each of the X direction and the Y direction, and regions having the plurality of end cells are different in an electric property from the unit cells UR and UL.

### CROSS-REFERENCE TO RELATED APPLICATION

The present application claims priority from Japanese Patent Application No. 2023-124235 filed on Jul. 31, 2023, the content of which is hereby incorporated by reference into this application.

### TECHNICAL FIELD OF THE INVENTION

The present invention relates to a power semiconductor device and a cell data generating system.

### BACKGROUND OF THE INVENTION

A mainstream of related-art power metal insulator semiconductor field effect transistors (MISFET) as a type of power semiconductor devices is a power MISFET (referred to as Si power MISFET below) using a silicon (Si) substrate. To the contrary, a power MISFET (referred to as SiC power MISFET below) using a silicon carbide (SiC) substrate (referred to as SiC substrate below) can achieve higher withstand voltage and lower loss than those of the Si power MISFET. Thus, attraction has been paid particularly to the SiC power MISFET (SiC power device) in the field of power-saving or environment-conscious inverter techniques.

The SiC power MISFET can achieve lower on-resistance at the same withstand voltage level than the Si power MISFET. This is because silicon carbide (SiC) is seven times larger in dielectric breakdown electric field strength than silicon (Si) and enables an epitaxial layer to be thinner than a drift layer.

A chip of the power semiconductor device is configured such that a plurality of unit cells of MISFET are arranged in a matrix pattern in plan view. Japanese Patent Application Laid-open Publication (Translation of PCT Application) No. 2020-512682 (Patent Document 1) describes a configuration in which a plurality of power MOSFET cells including a gate trench are arranged in an active region. In this case, end trenches are arranged in an end region surrounding the active region.

### SUMMARY OF THE INVENTION

In the SiC power device, ions tend to be deeply implanted in order to moderate an insulator electric field. A thick resist mask is required for deeply implanting the ions, and therefore, a side surface of a resist pattern easily tilts near an end portion of a region to be exposed to light by use of the resist mask. Consequently, a profile of an impurity region (semiconductor region) in the SiC substrate is collapsed to cause a problem that is decrease in chip performance.

Other objects and novel characteristics will become apparent from the description of the specification and the accompanying drawings.

The outline of the typical aspects of the embodiments disclosed in the present application will be briefly described as follows.

A power semiconductor device according to an embodiment includes: first unit cells and second unit cells which are cyclically arranged in a first direction and a second direction perpendicular to each other; and a plurality of end cells. The first unit cell and the second unit cell are alternately arranged in the first direction, and the plurality of end cells include a first end cell, a second end cell, a third end cell, a fourth end cell, and a fifth end cell. Each number of arrangement cycles of the first unit cells and the second unit cells in the second direction changes depending on repetition cycle coordinates of each of the first unit cells and the second unit cells in the first direction, each of the first unit cells and the second unit cells which are cyclically arranged is adjacent to any of the plurality of end cells at an endmost portion of the cyclic arrangement in each of the first direction and the second direction, and regions having the plurality of end cells are different in an electric property from the first unit cell and the second unit cell.

A cell data generating system according to an embodiment executes generation of arrangement data for cyclically arranging first unit cells and second unit cells in a first direction and a second direction perpendicular to the each other, and generation of arrangement data of a plurality of end cells. The first unit cell and the second unit cell are alternately arranged in the first direction, the plurality of end cells include a first end cell, a second end cell, a third end cell, a fourth end cell, and a fifth end cell, and each number of arrangement cycles of the first unit cells and the second unit cells in the second direction change depending on repetition cycle coordinates of each of the first unit cells and the second unit cells in the first direction. Each of the first unit cells and the second unit cells which are cyclically arranged is adjacent to any of the plurality of end cells at an endmost portion of the cyclic arrangement in each of the first direction and the second direction, and regions having the plurality of end cells are different in an electric property from the first unit cell and the second unit cell.

The effects obtained by the typical aspects of the present invention will be briefly described below.

According to the present invention, performance of a power semiconductor device can be improved.

### BRIEF DESCRIPTIONS OF THE DRAWINGS

FIG. 1 is a flowchart depicting operations of a cell data generating system according to a first embodiment.

FIG. 2 is a plan view depicting a power semiconductor device according to the first embodiment.

FIG. 3 is a cross-sectional view taken along the line A-A of FIG. 2.

FIG. 4 is a cross-sectional view for explaining the operations of the cell data generating system according to the first embodiment.

FIG. 5 is a cross-sectional view for explaining the operations of the cell data generating system, continued from FIG. 4.

FIG. 6 is a cross-sectional view for explaining the operations of the cell data generating system, continued from FIG. 5.

FIG. 7 is a plan view depicting the power semiconductor device according to the first embodiment.

FIG. 8 is a cross-sectional view taken along the line B-B of FIG. 7.

FIG. 9 is a cross-sectional view taken along the line C-C of FIG. 7.

FIG. 10 is a plan view depicting the power semiconductor device according to the first embodiment.

FIG. 11 is a cross-sectional view taken along the line D-D of FIG. 10.

FIG. 12 is a cross-sectional view taken along the line E-E of FIG. 10.

FIG. 13 is a plan view depicting a power semiconductor device according to a fourth comparative example.

FIG. 14 is a plan view depicting the power semiconductor device according to the first embodiment.

FIG. 15 is a cross-sectional view taken along the line F-F of FIG. 14.

FIG. 16 is a cross-sectional view taken along the line G-G of FIG. 14.

FIG. 17 is a plan view depicting a power semiconductor device according to a second embodiment.

FIG. 18 is a flowchart depicting operations of a cell data generating system according to the second embodiment.

FIG. 19 is a plan view depicting a power semiconductor device according to a third embodiment.

FIG. 20 is a cross-sectional view taken along the line H-H of FIG. 19.

FIG. 21 is a cross-sectional view for explaining operations of a cell data generating system according to a first modification example of the third embodiment.

FIG. 22 is a cross-sectional view for explaining the operations of the cell data generating system, continued from FIG. 21.

FIG. 23 is a cross-sectional view for explaining the operations of the cell data generating system, continued from FIG. 22.

FIG. 24 is a cross-sectional view for explaining operations of a cell data generating system according to a second modification example of the third embodiment.

FIG. 25 is a cross-sectional view for explaining the operations of the cell data generating system, continued from FIG. 24.

FIG. 26 is a cross-sectional view for explaining the operations of the cell data generating system, continued from FIG. 25.

FIG. 27 is a cross-sectional view depicting a power semiconductor device according to a first comparative example.

FIG. 28 is a cross-sectional view depicting a power semiconductor device according to a second comparative example.

FIG. 29 is a plan view depicting a part of a power semiconductor device according to a third comparative example.

FIG. 30 is a plan view depicting a part of the power semiconductor device according to the fourth comparative example.

### DESCRIPTIONS OF THE PREFERRED EMBODIMENTS

Hereinafter, embodiments of the present invention will be described in detail with reference to the accompanying drawings. Note that components having the same function are denoted by the same reference signs throughout all the drawings for describing the embodiments, and the repetitive description thereof will be omitted. In addition, the description of the same or similar portions is not repeated in principle unless otherwise particularly required in the following embodiments. Also, in some drawings for explaining the embodiments, hatching may be used even in a plan view or a perspective view so as to make the structure easy to see. Further, in some drawings for explaining the embodiments, hatching may be omitted in a cross-sectional view so as to make the structure easy to see.

Each of terms “−” and “+” is a sign indicating a relative impurity concentration of a conductive type “n” or “p”, and, for example, the n-type impurity concentration is higher in the order of “n⁻”, “n” and “n⁺”.

In this application, a metal oxide semiconductor field effect transistor (MOSFET) as a type of the MISFET will be described.

### <Details of Room to be Improved>

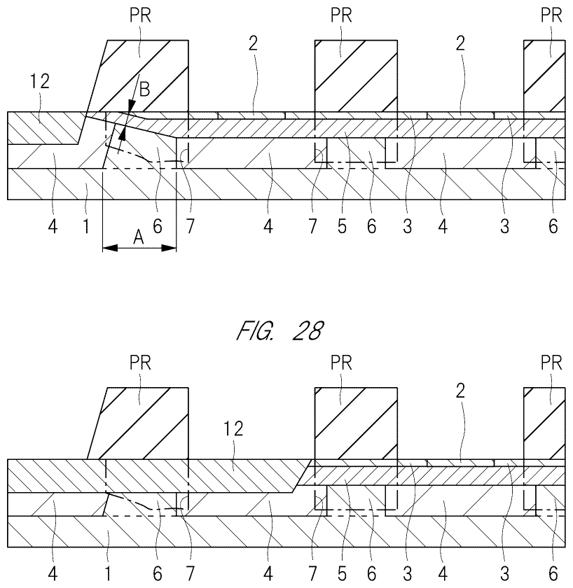

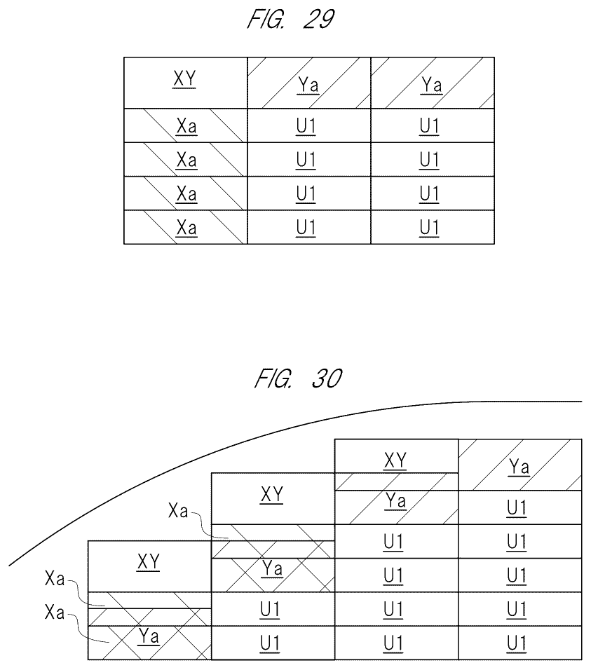

A room to be technically improved in the power semiconductor device will be described below with reference to FIGS. 27 to 30. FIG. 27 is a cross-sectional view depicting a power semiconductor device according to a first comparative example. FIG. 28 is a cross-sectional view depicting a power semiconductor device according to a second comparative example. FIG. 29 is a plan view depicting a part of a power semiconductor device according to a third comparative example. FIG. 30 is a plan view depicting a part of a power semiconductor device according to a fourth comparative example.

A semiconductor region (impurity region, impurity implantation region) configuring the power semiconductor device is formed by, for example, implanting impurity ions into a main surface of a wafer that is a semiconductor substrate or a rear surface opposite to the main surface. The impurity ions are implanted into the semiconductor substrate via a resist pattern made of a photoresist film, and therefore, can be introduced into a desired position of the semiconductor substrate. In a resist pattern forming step, a resist liquid to be the photoresist film is applied onto the main surface of the semiconductor substrate, and the photoresist film is exposed to light via a mask, and then, is developed (ashing process) to form the resist pattern with a desired pattern.

Optical cyclicity easily collapses at an end portion of a region for the light exposure. One of causes of this is that the resist pattern is not sufficiently larger than a wavelength of the light in the light exposure. Further, the resist liquid is applied by spin coating, and thus, if the developer is retained, reactivity of the photoresist film may be varied by the developer. By such a cause, a side surface of the resist pattern at the end portion of the exposed region is easily tilted.

As a first comparative example, FIG. 27 is a cross-sectional view depicting a state in which a p-type impurity is implanted into a semiconductor substrate 1 via a photoresist film PR that is the resist pattern to form a guard region 4. In FIG. 27, contours of trenches 7 which are formed on the main surface of the semiconductor substrate 1 and which are positioned in a depth direction of the drawing are illustrated with dashed dotted lines. In a unit cell forming region close to the center of the exposed region, the photoresist film PR has a side surface almost perpendicular to the main surface of the semiconductor substrate 1. To the contrary, at an end portion of the exposed region (on the left side of FIG. 27), the side surface of the photoresist PR is tilted because of the above reasons.

The guard region 4 that is the p-type semiconductor region is formed immediately below an opening of the photoresist film PR. However, the guard region 4 is formed to shallow below the tilted photoresist film PR since the ions are decelerated halfway when being implanted. Thus, the shape of the guard region 4 is collapsed. Because of the same reason, at the end portion, shapes of a semiconductor region including a body region 5 which is a MOSFET channel forming region and a trench 7 are collapsed.

A junction field effect transistor (JFET) region 6 that is an n-type impurity region is formed in the semiconductor substrate 1 between adjacent guard regions 4. In the cross-sectional views including FIG. 27 in this application, a lower end of the JFET region 6 is illustrated with a broken line. The ion implantation under use of the tilted photoresist film PR as the mask causes, at the end portion, a risk of increase in a width “A” of the JFET region 6 along the main surface of the semiconductor substrate 1 and decrease in a channel width “B” of the MOSFET. This case causes a problem of decrease in a threshold of the MOSFET configuring the power semiconductor device. In the SiC power device, the ions tend to be deeply implanted in order to moderate the insulator electric field. A thick resist mask is required in order to deeply implant the ions. Thus, at the end portion of the region to be exposed to light under the use of the resist mask, the side surface of the resist pattern is particularly easily tilted.

The power semiconductor device is a semiconductor chip including a plurality of MOSFET cells arranged in a matrix pattern, and a plurality of such semiconductor chips are prepared to be used while being connected in parallel. Total performance of the parallel-connected power semiconductor devices depends on particularly a low performance element of the semiconductor chips. Therefore, the total performance of the power semiconductor devices needs to be improved by preventing failure at the end portion.

As a method for this, there is a method of previously inactivating a part of the end portion where the shape of the semiconductor region is expected to be easily collapsed. That is, a pattern of the end portion is made of a dummy pattern with different property from those of the unit cells. In this case, as depicted in FIG. 28 as the second comparative example, a p⁺-semiconductor region 12 extending from the main surface of the semiconductor substrate 1 and reaching a deeper position than that of a source region 2 that is an n⁺-type semiconductor region is formed at the end portion. The p⁺-type semiconductor region 12 is higher in impurity concentration than the source region 2. As a result, the source region 2 is not present at the end portion, and the threshold remarkably increases. Consequently, the cell at the end portion does not operate as the MOSFET and is inactivated. That is, even if the shapes of the guard region 4, the trench 7 and the like are collapsed, adverse effect on the chip operations can be prevented. The p⁺-type semiconductor region 12 can be formed by ion implantation of introducing a p-type impurity (such as aluminum (Al)) into the semiconductor substrate 1.

FIG. 29 depicts a plane layout of a power semiconductor device according to a third comparative example in which the exposed region is assumed to be rectangular. In this case, unit cells (cyclic cells) U1 configuring the power semiconductor device are cyclically arranged in an “X” direction and a “Y” direction. In this application, The X direction is described as a direction along the main surface of the semiconductor substrate while the Y direction is described as being perpendicular to the X direction in plan view. A “Z” direction is a thickness direction of the semiconductor substrate and is a direction (vertical direction, depth direction) perpendicular to each of the X direction and the Y direction. Each of end cells Xa and Ya in FIGS. 29 and 30 is hatched in order to clearly demonstrate overlaps between the end cells.

When an entire plane shape of the unit cells U1 arranged in the matrix pattern is rectangular as depicted in FIG. 29, cell data of end cells Xa, Ya, and XY to be inactivated are easily created even manually. In this application, cell data is design information of cell arrangement (layout). Here, the end cell Xa is arranged adjacent to the end portion of the unit cells U1 arranged in the X direction, and the end cell Ya is arranged adjacent to the end portion of the unit cells U1 arranged in the Y direction. The end cell XY is arranged adjacent to the X-directional end portion of the end cells Ya arranged in the X direction.

FIG. 30 depicts a plane layout of a power semiconductor device according to a fourth comparative example in which the end portion of the exposed region is curved in plan view. The region depicted in FIG. 30 is a periphery (such as a corner) of the semiconductor chip, and the contour of the periphery of the exposed region is illustrated with a curved line. In this case, there is a reason to desirably maximally utilize an area of the SiC substrate since wafer cost of the SiC substrate is high. Thus, it is desirable to arrange the unit cells U1 as many as possible even in a non-rectangular region in the chip periphery. Therefore, the entire shape of the unit cells U1 arranged in the matrix pattern in the X direction and in the Y direction is not the rectangular shape but a shape in which at least the corner has a curvature. That is, the number of unit cells U1 is not uniform among columns, and the number is not uniform among rows, either. In this case, the end cells Xa, Ya, and XY mutually interfere, and therefore, remarkably complicated works are required to manually create the cell data.

That is, if the plurality of unit cells U1 are arranged within the rectangular region as depicted in FIG. 29, the end cells Xa, Ya, and XY of eight types at a maximum are prepared, and it is sufficient to repeatedly arrange the end cells Xa, Ya, and XY, and therefore, the cell data can be simply and easily created. To the contrary, if the contour of the arrangement region of the unit cells U1 is substantially curved as depicted in FIG. 30, the numbers of unit cells U1 adjacent to the end cells Xa, Ya, and XY are not constant in arbitrary regions near the curved portion, and therefore, it is necessary to estimate a large number of end patterns.

The manual creation of the cell data of the end cells in the non-rectangular region needs a remarkably large number of works, and easily causes mistakes in the creation and higher cost. Thus, a method capable of mechanically arranging the end cells irrespective of the chip shape and the device structure has been awaited. That is, there is a room to be improved in order to achieve a cell data generating system capable of, with a minimum number of types of cells, automatically generating cell data appropriately operable even if the plurality of end cells overlap or interfere, and to form a power semiconductor device using the system.

The following embodiments employ a devisal for solving the room to be improved. A technical concept of the first embodiment with this devisal will be described below.

### First Embodiment

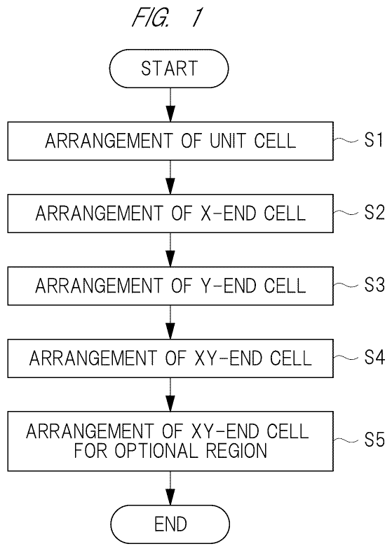

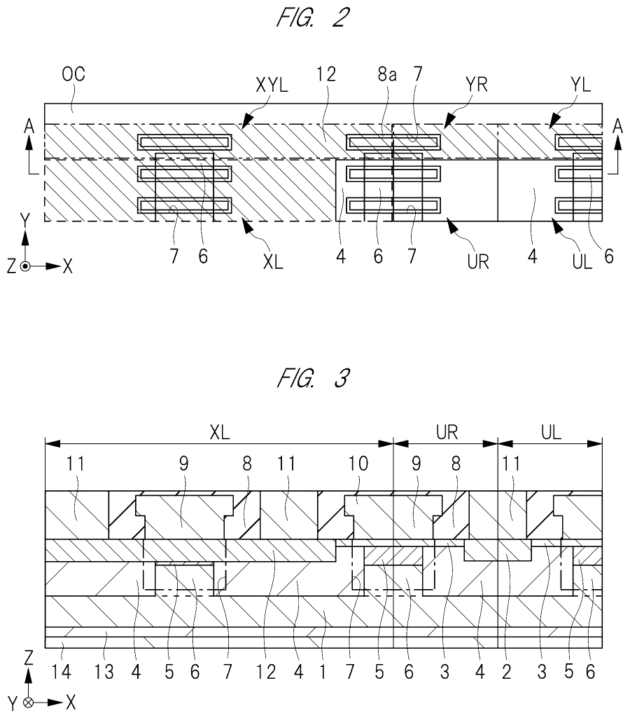

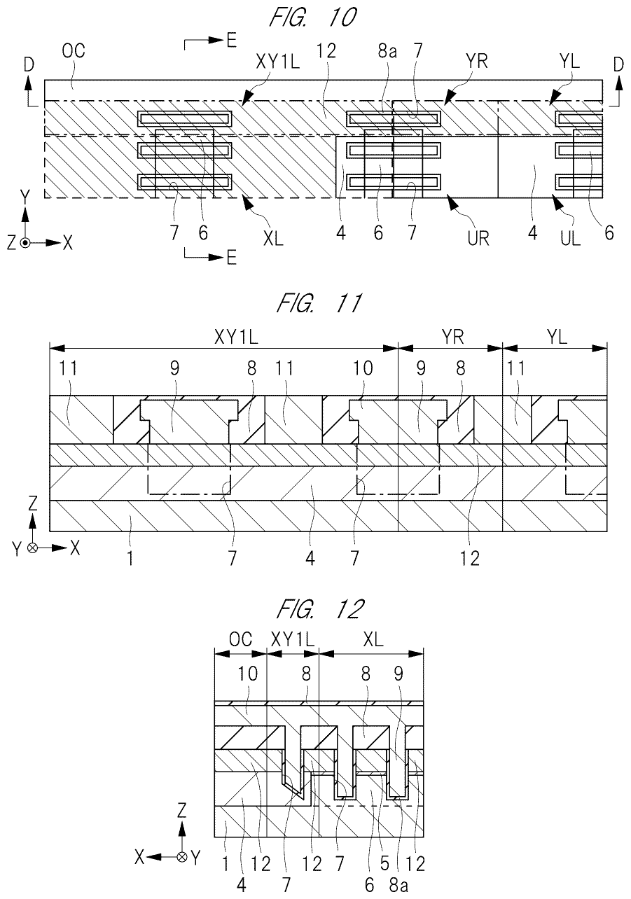

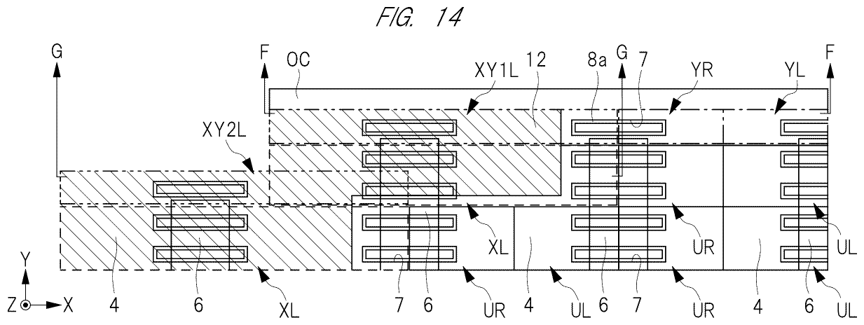

FIG. 1 is a flowchart depicting operations of a cell data generating system according to the present embodiment. The operations of the cell data generating system and a configuration of a power semiconductor device according to the present embodiment will be described below using FIGS. 2 to 12 and 14 with reference to FIG. 1.

First, the cell data generating system generates cell data of unit cells arranged in the matrix pattern in the X direction and in the Y direction (step S1 of FIG. 1). Next, the cell data generating system generates cell data of the X-end cells at the end portions of the unit cells in the X direction (step S2 of FIG. 1). Note that the structures including the inside of the trench on the semiconductor substrate, such as the gate electrode, the gate wiring, the interlayer insulative film, and the source wiring are not depicted in the plan views including FIG. 2 of this application. The body region, the source region, and the n-type semiconductor region (current diffusion region) formed in the semiconductor substrate are not depicted in the plan views, and only the guard region 4, the p⁺-type semiconductor region 12, the JFET region 6, the trench 7, and a gate insulative film 8a in the trench 7 are depicted in the plan views. The guard region 4 is formed in all the regions not overlapping the JFET region 6 in each plan view.

A place where the p⁺-type semiconductor region 12 is to be formed is hatched in FIG. 2. In order to clearly demonstrate the place where the p⁺-type semiconductor region 12 is to be formed, the hatching overlaps the inside of the trench 7 and the gate insulative film 8a in the trench 7 in FIG. 2. Actually, the p⁺-type semiconductor region 12 is shallower than the trench 7, and therefore, the p⁺-type semiconductor region 12 is formed only outside the trench 7. In FIG. 2, each contour of unit cells UR and UL is illustrated with a solid line, and a contour of an X-end cell XL is illustrated with a broken line. Each contours of Y-end cells YR and YL described below is illustrated with a dashed dotted line, and a contour of an XY-end cell XYL is illustrated with a dashed double-dotted line. An outside-cell region OC is present in a region adjacent to the Y-end cells YR and YL and the XY-end cell XYL and opposite to the unit cells UR and UL. The guard region 4 is formed in the semiconductor substrate 1 of the outside-cell region OC. Note that the lines illustrating the contours of the respective cells mutually overlap. However, some contour lines separate from one another in order to clearly demonstrate each plan view.

A configuration of the unit cell will be described below. Here, the active regions operable as the switching devices are arranged as the unit cells. The unit cell UR and the unit cell UL are alternately arranged in the X direction as depicted in FIG. 2. The unit cell UR and the unit cell UL are adjacent to each other and are axisymmetric to each other across a boundary therebetween. Actually, the respective configurations of the unit cell UR and the unit cell UL may not be axisymmetric. The power semiconductor device according to the present embodiment includes the semiconductor substrate 1 as depicted in FIG. 3. The semiconductor substrate 1 includes an n-type semiconductor region (drift layer).

A plurality of trenches 7 reaching a depth in the middle of the semiconductor substrate 1 are formed in the main surface of the semiconductor substrate 1. The trenches 7 extend in the X direction and are arranged in the Y direction and the X direction. The source region 2 that is an n⁺-type semiconductor region is formed to extend from the main surface of the semiconductor substrate 1 to a depth in the middle of the semiconductor substrate 1. The source region 2 extends in the Y direction and is formed shallower than the trench 7. The source region 2 is positioned between adjacent trenches 7 in the X direction and is separated from the trenches 7. A semiconductor region which is the semiconductor substrate 1 between adjacent trenches 7 in the Y direction, configures a fin which extends in the X direction and has small thickness in the Y direction. The MOSFET according to the present embodiment is also referred to as FIN-type MOSFET because of including a channel formed in the fin.

The n-type semiconductor region (current diffusion layer) 3 is formed on the main surface of the semiconductor substrate 1 at a predetermined depth in a portion between adjacent source regions 2 in the X direction. That is, the n-type semiconductor region 3 is in contact with the source regions 2. The n-type semiconductor region 3 is shallower than the source regions 2. The p-type guard region 4 is formed in the semiconductor substrate 1 between adjacent tranches 7 in the X direction. The guard region 4 is continuously in contact with the lower surface and side surface of the source region 2 and the lower surface of the n-type semiconductor region 3, and covers the lower end of the source region 2. The guard region 4 is deeper than the trench 7, and the lower end of the guard region 4 is positioned at a depth in the middle of the semiconductor substrate 1. The end of the guard region 4 in the X direction is adjacent to a part of the trench 7 in the Y direction.

Two guard regions 4 separate from each other between adjacent trenches 7 in the Y direction, and the body region 5 where the MOSFET channel is formed is formed in the semiconductor substrate 1 between the guard regions 4. The upper end of the body region 5 is in contact with the lower end of the n-type semiconductor region 3, and the body region 5 is shallower than the trench 7. A region which is between the lower end of the body region 5 and the lower end of the trench 7 and which is sandwiched between adjacent guard regions 4 in the X direction configures the JFET region 6. The JFET region 6 is an n-type semiconductor region sandwiched between the p-type semiconductor regions, and is lower in n-type impurity concentration than the n-type semiconductor region 3, the source region 2, and a drain region 13 described below. The n-type impurity concentration of the JFET region 6 may be higher than the n-type impurity concentration of the semiconductor substrate (drift layer) 1 or may be equal to the n-type impurity concentration of the semiconductor substrate (drift layer) 1.

In the fin that is the semiconductor substrate 1 adjacent to the side surface of the trench 7 in the Y direction, the n-type semiconductor region 3, the body region 5, and the JFET region 6 are arranged sequentially from the main surface of the semiconductor substrate 1 toward the rear surface thereof.

The drain region 13 that is an n⁺-type semiconductor region is formed at a predetermined depth on the rear surface opposite to the main surface of the semiconductor substrate 1. The upper end of the drain region 13 separates from the lower end of the guard region 4. A drain electrode 14 containing, for example, Au (gold) or the like is formed to cover the rear surface of the semiconductor substrate 1. A gate electrode 9 is embedded in the trench 7 via the gate insulative film 8a (see FIG. 2). An interlayer insulative film 8 mainly made of, for example, a silicon oxide film is formed on the semiconductor substrate 1. The gate electrode 9 formed immediately above the trench 7 and a gate wiring 10 unified with and formed on the gate electrode 9 are formed in the interlayer insulative film 8. The gate wiring 10 extends in the Y direction to overlap the plurality of trenches 7 and is connected to the plurality of gate electrodes 9. Note that the drain region 13 and the drain electrode 14 are not depicted in the cross-sectional views except for FIG. 3.

A source wiring (source contact plug, conductive connection portion) 11 mainly made of, for example, aluminum (Al) is formed in a through-hole penetrating the interlayer insulative film 8 in the Z direction. The source wiring 11 extends in the Y direction and is connected to the source region 2 at its bottom. Note that a silicide layer may be present between the source wiring 11 and the source region 2. The source region 2, the drain region 13, the gate electrode 9, and the body region 5 configure the MOSFET (trench MOSFET). Though not depicted, a source pad connected to each source wiring 11 is formed on the interlayer insulative film 8. When the MOSFET is conducted, electrons supplied from the source wiring 11 flow to the drain region 13 and the drain electrode 14 sequentially via the source region 2, the n-type semiconductor region 3, the body region 5, and the JFET region 6.

The body region 5 adjacent to the trench 7 in the Y direction configures the trench MOSFET structure. The drain of the trench MOSFET structure is connected to the source of the JFET region 6. That is, the terminal (lower end) of the body region 5 close to the drain is connected to the terminal (upper end) of the JFET region 6 close to the source.

As depicted in FIG. 2, the JFET region 6 that is the active region of the unit cells UR, UL extends in the Y direction to overlap the plurality of trenches 7 arranged in the Y direction. Though not depicted in FIG. 2, the plurality of unit cells UR and UL are arranged in the X direction and are alternately formed at the same cycle in the Y direction. The unit cells UR arranged in the Y direction share the source region 2, the n-type semiconductor region 3, the guard region 4, and the JFET region 6 which extend in the Y direction.

Next, the X-end cell XL which is positioned at the end portion of the unit cells UR and UL arranged in the X direction will be described. Each end cell partially has the common structure with the structures of the unit cells UR and UL, and therefore, differences in the structures from the unit cells UR and UL will be described in the explanation for the end cell structure. As described above with reference to FIG. 29, in order to suppress the influence on the pattern collapse at the cell arrangement end, the JFET region 6 similar to the JFET region 6 formed in the unit cell UR, UL, and the trench 7 are formed at the end portion, and the p⁺-type semiconductor region 12 is arranged to overlap the JFET region 6 or the MOSFET structure in the X-end cell XL to achieve the inactivation. The MOSFET structure herein is, for example, the n-type semiconductor region 3 and the body region 5.

As depicted in FIGS. 2 and 3, the X-end cell XL includes the guard region 4, the body region 5, the JFET region 6, the trench 7, the gate insulative film 8a, the gate electrode 9, the gate wiring 10, and the source wiring 11 which are formed at the same cycle as those of the unit cells UR, UL. The p⁺-type semiconductor region 12 is formed to extend from the main surface of the semiconductor substrate 1 to a depth in the middle of the semiconductor substrate 1. The depth of the p⁺-type semiconductor region 12 is, for example, equal to or larger than the depth of the source region 2. Here, the p⁺-type semiconductor region 12 is shallower than the body region 5, but may be deeper than the body region 5.

The p⁺-type semiconductor region 12 is formed in the entire X-end cell XL except for the end portion in contact with the unit cell UR in the X direction in plan view. That is, the X-end cell XL includes the p⁺-type semiconductor region 12 which separate from the body region 5, the JFET region 6, and the trench 7 which are shared with its adjacent unit cell UR in the X direction and which overlaps the other body region 5 and JFET region 6 in plan view. As a result, the decrease in the width (also referred to as JFET width below) of the JFET region 6 formed at the end portion of the unit cell UR is prevented. The source wiring 11 formed in the X-end cell XL is positioned immediately above the p⁺-type semiconductor region 12 and is electrically connected to the p⁺-type semiconductor region 12.

In the X-end cell XL, since the p⁺-type semiconductor region 12 is arranged above the JFET region 6, the current path disappears, and the channel threshold is remarkably increased, and consequently the MOSFET is not turned ON. Since there is no source region 2 in the MOSFET, the current conduction of the cell is suppressed.

Only one cycle of the X-end cell XL including the inactive JFET region 6 and MOSFET structure is depicted in FIG. 3. However, two or more cycles of the X-end cell XL may be arranged in the X direction. In this case, an X-end cell XR which has a structure axisymmetric to the X-end cell XL is arranged adjacent to the X-end cell XL. The number of cycles may be different between the JFET region 6 and the MOSFET structure. However, the more the X-end cells is, the smaller the area of the active cells is. Therefore, the chip performance of the power semiconductor device decreases. A range of the occurrence of the pattern collapse depends on a process condition, and therefore, is not constant. However, occurrence of the pattern collapse in two or more cycles is not rare. Thus, it is required to select the optimum numbers of arrangement cycles in consideration of the required active area and the influence of the pattern collapse.

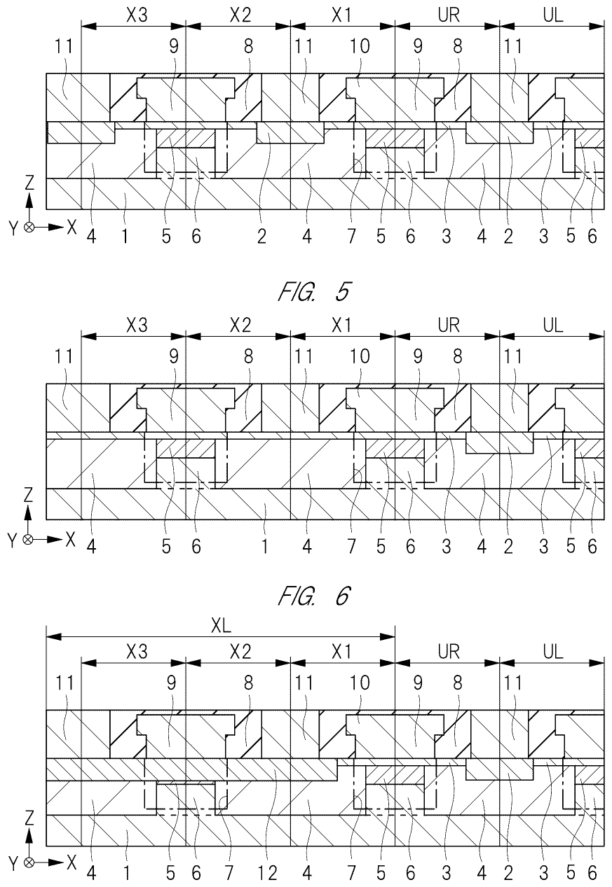

Next, a specific procedure of generating the cell data of the unit cell in step S1 of FIG. 1 and a specific procedure of generating the cell data of the X-end cell in step S2 will be described below with reference to FIGS. 4 to 6. FIGS. 4 to 6 depict not an actual power semiconductor device manufacturing process but a cell data (layout information) generating process.

First, the unit cells UR and UL are alternately arranged as depicted in FIG. 4 (step S1 of FIG. 1). In this case, the unit cells are arranged to correspond to the number of cycles of the inactive cells and the end portions of the JFET region 6. That is, the same cell data as those of the unit cells UR and UL is repeatedly arranged in the region to be the X-end cell. In other words, the unit cells UL and UR and a region corresponding to the unit cell UL are arranged in the X direction in the X-end cell. The regions arranged in the X direction to correspond to the unit cells in the X-end cell are referred to as a first cell X1, a second cell X2, and a third cell X3 in the order from the side close to the unit cells UR and UL below. The phrase “the order from the side close to the unit cells UR and UL” means that “the order from the center of the power semiconductor device (the center of the exposed region) in the X direction.”

Next, as depicted in FIG. 5, the n-type semiconductor region which is electrically close to the source than the channel (the body region 5 shared with the unit cell UR) and which is higher in impurity concentration than the p⁺-type semiconductor region 12 formed in the step described below is removed from all of the first cell X1, the second cell X2, and the third cell X3. That is, the source region 2 is removed from the cell data of the first cell X1, the second cell X2, and the third cell X3. In other words, the design for the formation of the source region 2 is cancelled in the first cell X1, the second cell X2, and the third cell X3.

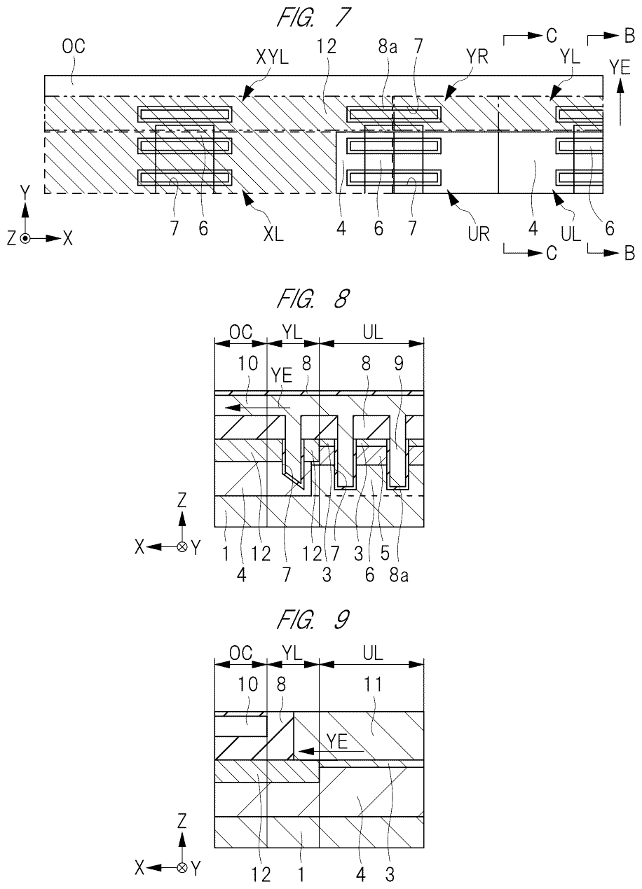

Next, the p⁺-type semiconductor region 12 is arranged to totally cover at least the JFET region 6 formed at the end cell as depicted in FIG. 6. In other words, the p⁺-type semiconductor region 12 is arranged to overlap the body region 5 or the JFET region 6 in the MOSFET structure in plan view. When the source wiring 11 of the first cell X1, the second cell X2, or the third cell X3 is defined to straddle the unit cell, the guard region 4, the p⁺-type semiconductor region 12, and a contact mask are expanded as needed. As a result, the cell data of the X-end cell XL (XR) made of the first cell X1, the second cell X2, and the third cell X3 can be generated.

In this case, the n-type semiconductor region which is higher in impurity concentration than the p⁺-type semiconductor region 12 is removed in FIG. 5. However, for example, if the source region 2 is lower in impurity concentration than the p⁺-type semiconductor region 12, the source region 2 may be not removed but left. In this case, the higher-concentration p⁺-type semiconductor region 12 is formed to overlap the source region 2, and the source region 2 is to be a p-type semiconductor region.

Next, the cell data generating system generates the cell data of the Y-end cell at the end portion of the unit cell in the Y direction (step S3 of FIG. 1). Since the pattern collapse occurs also in the Y direction, the structure (such as the trench 7) configuring the channel is also arranged one or more cycles in the Y-end cell, and the p⁺-type semiconductor region 12 is arranged similarly as in the X direction to achieve the inactivation. A Y-end cell YR is adjacently arranged at the end portion of unit cell UR arranged in the Y direction as depicted in FIG. 7. A Y-end cell YL is adjacently arranged at the end portion of the unit cell UL arranged in the Y direction. The plane layout of FIG. 7 is the same as the plane layout of FIG. 2.

Here, in the structure in which the unit cells UR and UL are expanded or shrunk in the Y direction, objects other than the gate wiring 10 and the guard region 4 are cut (cancelled) in the middle of the Y-end direction YE. Next, the guard region 4 is arranged at a constant width from the Y-end direction YE. Finally, the p⁺-type semiconductor region 12 is arranged in the entire surface of the Y-end cell YR, YL to achieve the separation from the outside-cell region OC and the inactivation of the end cell.

The constant width may be a range of the entire surface of the Y-end cell YR, YL. This is because the pattern collapse of the JFET region 6 in the Y direction generally occurs in a region for safe operation, and is not important. To the contrary, the collapse of the trench 7 in the Y direction occurs in a region for risky operation such as the decrease in the threshold, and thus, needs to be reliably inactivated.

FIG. 7 depicts only one cycle in the Y direction as the MOSFET structure (trench 7) in the Y-end cells YR and YL as similar to those in the X-end cells XR and XL. However, two or more cycles of the MOSFET structure may be arranged. The number of cycles can be determined to be independent from the expansion width of the JFET region 6 to the Y-end cell YR, YL.

As depicted in FIGS. 7 to 9, the p⁺-type semiconductor region 12 is formed in the entire Y-end cells YR and YL in plan view. The Y-end cell YR, YL includes the JFET region 6 extending from its adjacent unit cell UR, UL. In plan view, the Y-end cell YR, YL includes the guard region 4 in all the regions other than where the JFET region 6 is formed. The trench 7 is covered with the p-type semiconductor regions (the p⁺-type semiconductor region 12 and the guard region 4) down to its lower end in the Y-end cells YR and YL, and therefore, the cells are inactivated.

That is, the trench 7 is a dummy trench in which the channel is not formed near its side surface. Even if the channel is formed near the side surface of the trench 7, the channel is not conducted.

That is, as compared to the cell structure in which the unit cells UR and UL are expanded or shrunk in the Y direction, the Y-end cells YR and YL are configured such that the components other than the gate wiring 10 and the guard region 4 are cut (cancelled) in the Y direction, such that the JFET region 6 is closed in the middle of the Y direction, and such that the p⁺-type semiconductor region 12 is arranged in the entire Y-end cells YR and YL.

As one feature of the present embodiment, as described later, when generating the arrangement data of the Y-end cells, the cell data generating system arranges the Y-end cell at a position adjacent to the end portion of the unit cells cyclically arranged in the Y direction unless the Y-end cell overlaps the X-end cell.

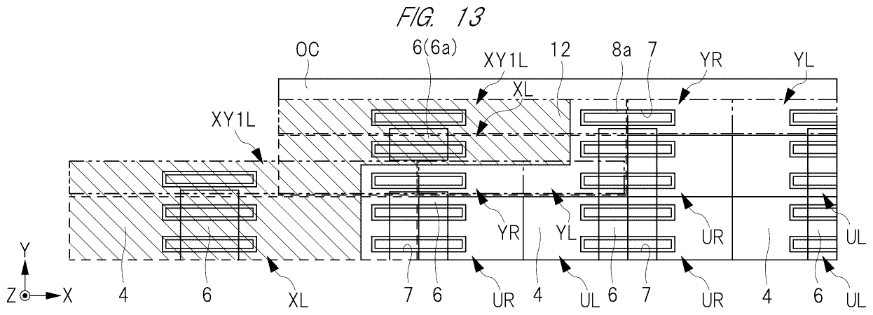

Next, the cell data generating system generates the cell data of the XY-end cell at the end portion of the X-end cell in the Y direction (step S4 of FIG. 1). As depicted in FIGS. 10 to 12, the XY-end cell XY1L can be created by a processing similar to that of creating the Y-end cell YL to the X-end cell XL. Though not depicted, the XY-end cell XY1R can be created by a processing similar to that of creating the Y-end cell YR to the X-end cell XR. Specifically, by the arrangement of the MOSFET structure (such as the trench 7), the entire XY-end cell may be inactivated by the p⁺-type semiconductor region 12. The plane layout of FIG. 10 is the same as the plane layouts of FIGS. 2 and 7.

The XY-end cell XY1L will be exemplified and described herein. However, the XY-end cell XY1R also has the same structure. The structure of the XY-end cell XY1L has similar characteristics to the Y-end cell YL. That is, the p⁺-type semiconductor region 12 is formed in the entire XY-end cell XY1L in plan view. The XY-end cell XY1L includes the JFET region 6 extending from its adjacent X-end cell XL. In plan view, the XY-end cell XY1L includes the guard region 4 in all the regions other than where the JFET region 6 is formed. The trench 7 is covered with the p-type semiconductor regions (the p⁺-type semiconductor region 12 and the guard region 4) down to its lower end in the XY-end cell XY1L, and the cell is inactivated.

That is, as compared to the cell structure in which the X-end cells are expanded or shrunk in the Y direction, the XY-end cell XY1L is configured such that the components other than the gate wiring 10 and the guard region 4 are cut (cancelled) in the Y direction, the JFET region 6 is closed in the middle of the Y direction, and the p⁺-type semiconductor region 12 is arranged in the entire XY-end cell XY1L. Since the p⁺-type semiconductor region 12 is formed in the region including each end cell, the MOSFET structure has a higher threshold voltage than those of the unit cells UR and UL.

The operations of the cell data generating system described above can create the cell data without any problem when the unit cells are arranged in the rectangular region as described in the third comparative example of FIG. 29. Only under the condition described above as one feature of the present embodiment, in other words, unless the Y-end cell overlaps the X-end cell, the creation of the cell data without the condition that the Y-end cell needs to be adjacently arranged at the end portion of the unit cell is no problem if the unit cells are arranged within the rectangular region. However, this case causes the following problems in the power semiconductor device in which the end portion of the exposed region is curved in plan view as described in the fourth comparative example of FIG. 30. Thus, it is required to further add conditions including the condition described above as one feature of the present embodiment to the cell data generating method.

FIG. 13 is a plan view depicting the power semiconductor device according to the fourth comparative example. The power semiconductor device is formed in accordance with the cell data generating system that arranges the X-end cell at the end portion of the unit cell in the X direction, arranges the Y-end cell at the end portion of the unit cell in the Y direction, and arranges the XY-end cell at the end portion of the X-end cell in the Y direction. The region in which the unit cells UR and UL are arranged has a curved end in plan view and is not of the simple rectangular shape. Thus, a part of the X-end cell XL arranged in accordance with the cell data generating system overlaps the Y-end cells YR and YL, and a part of the XY-end cell XY1L overlaps a part of the X-end cell XL.

The overlapped portions are inactivated since the p⁺-type semiconductor region 12 is present. However, various components overlap, and therefore, failures can occur. An abnormal shape of the guard region 4 as depicted in FIG. 13 is exemplified. In FIG. 13, the guard region 4 in the XY-end cell XY1L and the Y-end cell YR protrudes to divide the JFET region 6 to form an isolated pattern 6a in the JFET region 6. The formation of the isolated pattern 6a does not affect the operations. However, when such a fine isolated pattern 6a is formed, a fine resist pattern needs to be formed on the semiconductor substrate 1. A resist pattern that is a fine protrusion falls down during the steps of manufacturing the power semiconductor device, and easily becomes particles, and causes a decrease in yield in the manufacturing steps.

Accordingly, the present inventors have paid attention to the fact that the cell overlaps are potentially the overlap between the X-end cell XL and the Y-end cells YR and YL and the overlap between the portion corresponding to the unit cell UL that is arranged first in the generation of the end cell and the portion added for the contact. The present inventors have studied the cell arrangement in an optional region (optional shape region), and have solved the above-described problems by manufacturing the power semiconductor device under use of a cell data generating system described below.

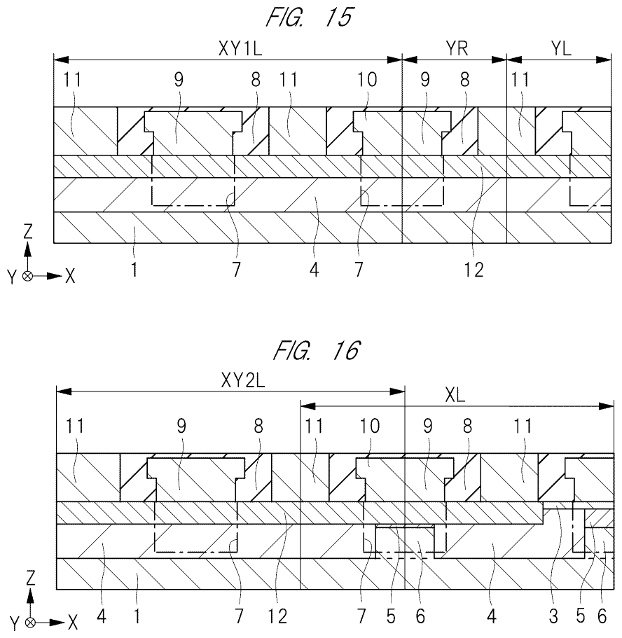

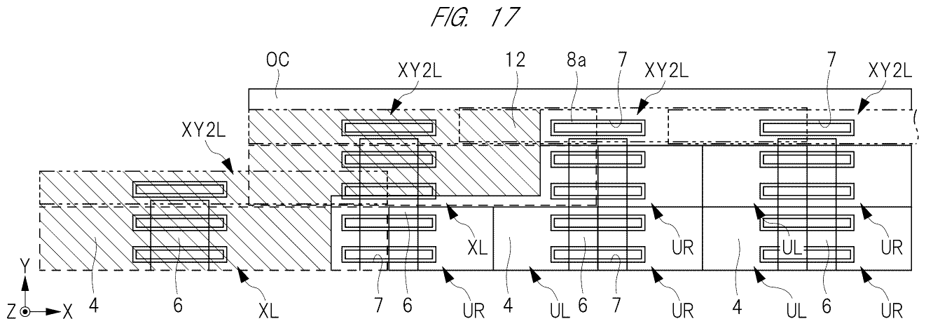

FIG. 14 is a plan view depicting the power semiconductor device according to the present embodiment. FIG. 15 is a cross-sectional view taken along the line F-F of FIG. 14, and FIG. 16 is a cross-sectional view taken along the line G-G of FIG. 14.

Assuming that the first cell X1, the second cell X2, and the third cell X3 (see FIG. 6) are included in the X-end cell XL at the same cycle as those of the unit cell UR, UL in this order from its adjacent unit cell UR in the X direction, the first cell X1 and the second cell X2 in the X-end cell XL have the same value in a cell data generating algorithm as those of the Y-end cell YR, YL. Thus, the Y-end cell does not need to be arranged in the column in which the X-end cell is present. That is, in generating the cell data of the Y-end cell (step S3 of FIG. 1), unless the Y-end cell overlaps the X-end cell, in other words, under the condition described above as one feature of the present embodiment, the Y-end cell is arranged based on the arrangement of the Y-end cell to be adjacent to the end portion of the unit cell. This arrangement is employed to eliminate the overlap between the Y-end cell and the X-end cell.

In terms of the generating algorithm, the first cell X1 in the XY-end cell XY1L is different from the unit cell UL only in that the JFET region 6 is closed, in other words, in that the JFET region 6 is ended in the Y direction. Thus, when the XY-end cell is to be arranged at a position adjacent to an end portion of a certain X-end cell in the Y direction, if other X-end cell is present in the same row as that of the column adjacent to this position, an XY-end cell XY2L for the optional region which is created by removing the guard region 4 from the first cell X1 at the end portion close to the unit cell UR is arranged as an XY-end cell with a different structure from that of the XY-end cell XY1L (step S5 of FIG. 1).

In other words, unless the X-end cell XL is arranged at the position adjacent thereto in the X direction, the XY-end cell XY1L is arranged adjacent to the end portion of the X-end cell XL in the Y direction. If the X-end cell XL is arranged at the position adjacent thereto in the X direction, the XY-end cell XY2L for the optional region is arranged adjacent to the end portion of the X-end cell XL in the Y direction. From the above, the isolated pattern 6a in the JFET region 6 as depicted in FIG. 13 can be prevented from occurring.

As compared to the cell structure in which the X-end cells are expanded or shrunk in the Y direction, the XY-end cell XY2L for the optional region is configured such that the components other than the gate wiring 10 and the guard region 4 are cut (cancelled) in the Y direction and such that the JFET region 6 is closed in the middle of the Y direction. Further, the XY-end cell XY2L for the optional region is configured such that the p⁺-type semiconductor region 12 is arranged in the entire XY-end cell XY2L for the optional region and such that the guard region 4 is removed from the first cell X1 close to the unit cell UR.

As depicted in FIGS. 14 to 16, the trench formed in the end cells such as the Y-end cells YR and YL, the XY-end cell XY1L, and the XY-end cell XY2L for the optional region is separated from the JFET region 6. That is, any of the plurality of end cells includes the trench not in connect with the JFET region 6. As a result, the trench MOSFET structure adjacent to the shape-collapsed trench can operate to prevent the decrease in the threshold of the MOSFET.

### <Effects of Embodiments>

As described above, the cell data generating system according to the present embodiment executes the generation of the arrangement data for cyclically arranging the unit cells UR and UL in the X direction and in the Y direction (step S1 of FIG. 1) and the generation of the arrangement data of the plurality of end cells (steps S2 to S5 of FIG. 1). The unit cells UR and UL are alternately arranged in the X direction, and the plurality of end cells include at least the X-end cell XL (first end cell), the Y-end cell YR (second end cell), the Y-end cell YL (third end cell), the XY-end cell XY1L (fourth end cell), and the XY-end cell XY2L (fifth end cell) for the optional region.

The numbers of arrangement cycles of the unit cells UR and UL in the Y direction change depending on the repetition cycle coordinates of the unit cells UR and UL in the X direction, respectively, and the cyclically-arranged unit cells UR and UL are adjacent to any of the plurality of end cells at the endmost portions of the respective arrangement cycles in each of the X direction and the Y direction. The regions including the plurality of end cells are different in the electric property from the first unit cell and the second unit cell.

In accordance with the flowchart of FIG. 1, the cell data generating system operates as follows. That is, in step S1, the cell data generating system cyclically arranges the unit cells UR and UL.

In step S2, the cell data generating system arranges the X-end cell XL or XR connected to the endmost portion of the unit cell UR, UL in the X direction.

In step S3, the cell data generating system arranges the Y-end cell YR at the position adjacent to the end portion of the unit cells UR cyclically arranged in the Y direction, unless the Y-end cell YR overlaps the X-end cell XL, XR. Similarly, the cell data generating system arranges the Y-end cell YL at the position adjacent to the end portion of the unit cells UL cyclically arranged in the Y direction, unless the Y-end cell YL overlaps the X-end cell XL, XR.

In step S4, the cell data generating system arranges the XY-end cell XY1L or XY1R at the position adjacent to the end portion of the X-end cell XL or XR in the Y direction, unless the X-end cell XL is arranged at the adjacent position in the X direction.

In step S5, the cell data generating system arranges the XY-end cell XY2L or XY2R at the position adjacent to the end portion of the X-end cell XL or XR in the Y direction, unless the X-end cell XL is arranged at the adjacent position in the X direction.

The power semiconductor device according to the present embodiment is equivalent to the structure generated by the cell data generating system.

Because of the X-end cells, Y-end cells, XY-end cells, and XY-end cells for the optional region generated and arranged as described above, the cells including the end portion structure can be automatically arranged for the optional chip shape. That is, the end cells can be mechanically arranged irrespective of the chip shape and the device structure. The present invention can achieve the cell data generating system capable of automatically generating, with a minimum number of types of cells, the cell data that is appropriately operable even when the plurality of end cells overlap or interfere with one another, and can form the power semiconductor device using the system, and therefore, can solve the room to be improved.

That is, the failure of the end portion of the power semiconductor device can be prevented to improve the total performance of the power semiconductor device. The decrease in yield caused by the presence of the isolated resist pattern as described with reference to FIG. 13 can be prevented. Also, the cell data can be automatically generated, and therefore, the increase in manufacture cost due to the manual cell data generation can be prevented, and occurrence of the mistakes in the generation can be also prevented.

### Second Embodiment

The first embodiment has been described such that the cell end structure can be achieved with the X-end cells, Y-end cells, XY-end cells, and XY-end cells for the optional region. The present embodiment will be described regarding a simpler algorithm without the Y-end cells YL and YR and the XY-end cell XY1L.

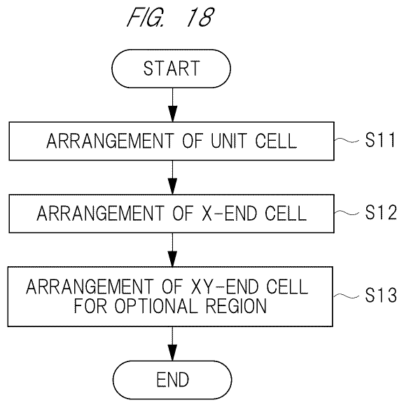

In the first embodiment, the Y-end cell is arranged in the column in which the XY-end cell for the optional region is not present. However, all the Y-end cells can be replaced with the XY-end cell for the optional region. In this case, as depicted in FIG. 17, the first cell and the third cell of the respective XY-end cells for the optional region adjacent to each other in the X direction overlap each other. The two cells are different from each other in that the guard region 4 is removed from the first cell. The overlapped portion with the third cell has the same value as that of the Y-end cell YL. To the contrary, the second cell has the same value as that of the Y-end cell YR, and therefore, the same structure as that in the case of the arrangement of the Y-end cells YR and YL is generated. Therefore, the Y-end cells are not needed.

The first embodiment has the problem that is the narrow JFET width in the first cell caused when the XY-end cell for the optional region is used for the XY-end cell adjacent to the Y-end cell. However, this problem is also solved by the overlap with the third cell, and the XY-end cell is not needed, either.

Note that the XY-end cell XY2L for the optional region can be overlapped with another XY-end cell XY2L for the optional region, and can be completely arranged from one end of the optional region in the X direction to the other end when being overlapped therewith in all regions where the Y-end cell was supposed to be arranged.

As described above, in the present embodiment, the Y-end cells and the XY-end cell have a structure equivalent to that of the XY-end cell for the optional region. Thus, as depicted in FIG. 18, the cell data generating system according to the present embodiment substantially completes the cell data generation by arranging the unit cell and the X-end cell in steps S11 and S12 as similar to the steps S1 and S2 of FIG. 1, and then, arranging the XY-end cell for the optional region (in step S13). In step S13, the XY-end cell for the optional region is arranged at the position adjacent to the end portion of each of the unit cell and the X-end cell in the Y direction.

### Third Embodiment

In the first and second embodiments, the end cells arranged in the X direction and in the Y direction are the cells having the constant JFET width and being completely inactivated by the p⁺-type semiconductor region. However, the cell which is present at the end portion of the active region does not share the current path of the epitaxial layer with other cells even when being a cell having the full JFET width without the pattern collapse, and therefore, larger current flows in this cell. Thus, an approach is also effective, the approach of forming the JFET region of the end cell not to be completely inactivated and gradually narrowing the JFET width toward the end portion of the power semiconductor device.

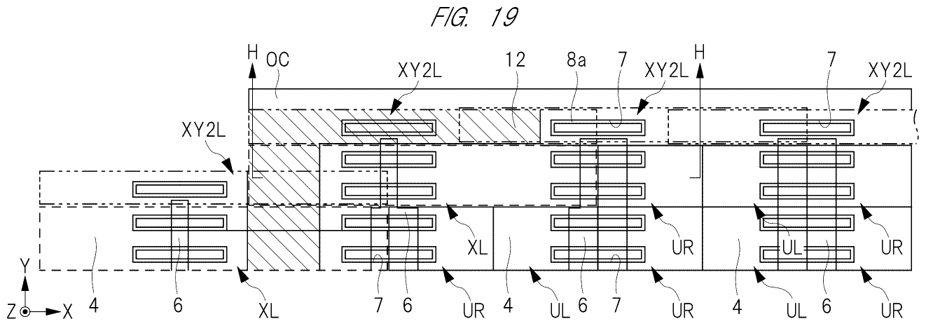

FIGS. 19 and 20 are a plan view and a cross-sectional view in a case of arrangement of one narrow JFET region at an end cell, respectively. FIG. 20 is a cross-sectional view taken along the line H-H of FIG. 19. As depicted in FIG. 19, the width of the JFET region 6 is narrower as getting closer to the end portions in not only the X direction but also the Y direction.

Two or more JFET regions 6 with mutually different JFET widths may be arranged in the X direction in each end cell. In a case of a MOSFET structure in which current laterally flows, it is also effective to use a MOSFET structure in which the cannel length is longer as getting closer to the end portion of the power semiconductor device. That is, the X-end cell XL according to the present embodiment has a different JFET width from those of the unit cells UR and UL or a different channel length from those of the unit cells UR and UL. Specifically, the X-end cell XL has the JFET width narrower as getting closer to the end portion of the power semiconductor device in the X direction, or the channel length longer as getting closer to the end portion of the power semiconductor device in the X direction, than those of the unit cells UR, UL.

In the present embodiment, since the JFET width is narrower as getting closer to the end portion, current disperses, and therefore, heat can be prevented from concentrating on, for example, the unit cell close to the end portion among the plurality of arranged unit cells.

The present embodiment has been described with reference to the drawings in which only the X-end cell and the XY-end cell for the optional region are arranged as the end cells as similar to the second embodiment. However, as similar to the first embodiment, the X-end cell, Y-end cell, XY-end cell, and XY-end cell for the optional region may be arranged.

### First Modification Example

The first to third embodiments are applicable also when the semiconductor element is a double-diffused MOSFET (DMOSFET). Also in the DMOSFET, the structure including the inactive cell at the end portion can be automatically generated by the methods according to the first to third embodiments.

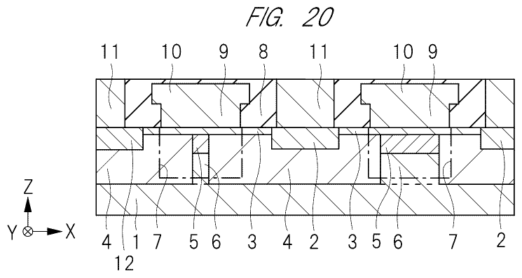

As depicted in FIG. 21, the DMOSFET includes: a p-type semiconductor region 4a formed to extend from the main surface of the n-type semiconductor substrate 1 to a depth in the middle; and the source region 2 formed in the p-type semiconductor region 4a to extend from the main surface of the n-type semiconductor substrate 1 to a depth in the middle of the p-type semiconductor region 4a. Though not depicted, the drain region 13 and the drain electrode 14 are formed in a region of the rear surface of the semiconductor substrate as similar to the MOSFET of FIG. 3. The trench is not formed in this case, and the gate electrode 9 is formed on the main surface of the flat semiconductor substrate 1 via the gate insulative film (the interlayer insulative film 8).

As depicted with an arrow in FIG. 21, when the DMOSFET is conducted, electrons supplied from the source wiring 11 flow to the drain region 13 and the drain electrode 14 sequentially via the source region 2, the p-type semiconductor region 4a, and the semiconductor substrate 1. The p-type semiconductor region 4a is a semiconductor region corresponding to the guard region 4 and the body region 5 described in the first embodiment. A channel is formed in the p-type semiconductor 4a sandwiched between the source region 2 and the semiconductor substrate 1 near the main surface of the semiconductor substrate 1.

The procedure of arranging the unit cells UR and UL and the X-end cell XL (generating the cell data) in steps S1 and S2 of FIG. 1 is similar to the steps described with reference to FIGS. 4 to 6. That is, first, the unit cells UR and UL are alternately arranged as depicted in FIG. 21 (step S1 of FIG. 1).

Next, as depicted in FIG. 22, the n-type semiconductor region which is electrically closer to the source than the channel (the p-type semiconductor region 4a) and is higher in impurity concentration than the p⁺-type semiconductor region 12 formed in a later-described step is removed from all of the first cell X1, the second cell X2, and the third cell X3. That is, the source region 2 is eliminated from the cell data of the first cell X1, the second cell X2, and the third cell X3. In other words, the design for forming the source region 2 in the first cell X1, the second cell X2, and the third cell X3 is cancelled.

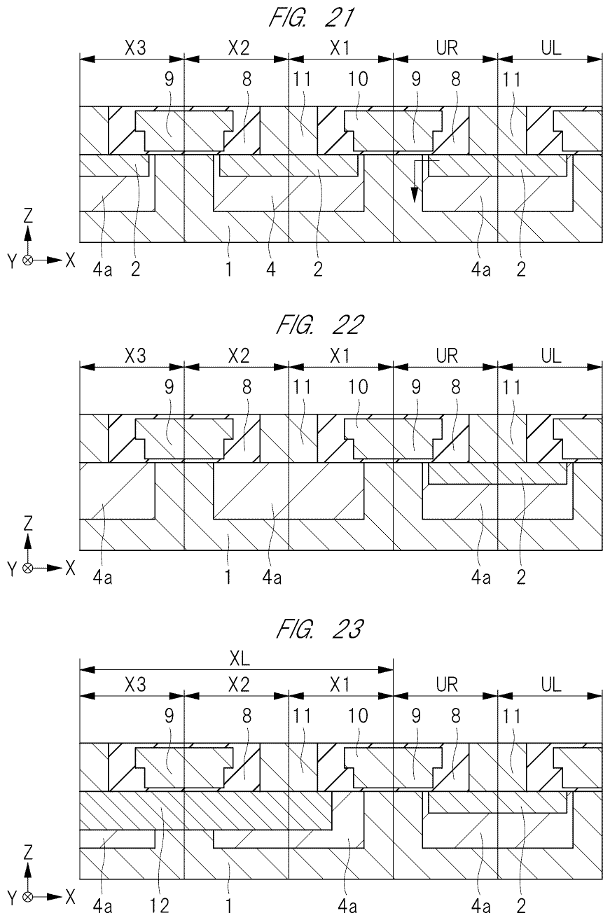

Next, as depicted in FIG. 23, the p⁺-type semiconductor region 12 is arranged to totally cover the semiconductor substrate 1 sandwiched between the adjacent p-type semiconductor regions 4a at least in the end cell. As a result, the cell data of the X-end cell XL (XR) made of the first cell X1, the second cell X2, and the third cell X3 can be generated.

### Second Modification Example

The first to third embodiments are applicable also when a special trench MOSFET including the source region formed deeper than the channel and including the drain region closer to the main surface of the semiconductor substrate than the channel is formed as the semiconductor device. This is because the operations of the MOSFET can be accurately inactivated by eliminating the region electrically close to the source from the MOSFET structure.

As depicted in FIG. 24, the trench MOSFET according to this modification example includes: the p-type semiconductor region 4a formed to extend from the main surface of the n-type semiconductor substrate 1 to a depth in the middle; and the source region 2 formed in the p-type semiconductor region 4a to extend from the main surface of the n-type semiconductor substrate 1 to a depth in the middle of the p-type semiconductor region 4a. The plurality of trenches 7 which are deeper than the source region 2 and shallower than the p-type semiconductor region 4a are formed in the main surface of the semiconductor substrate 1 to be arranged in the X direction and the Y direction. Though not depicted, as similar to the MOSFET of FIG. 3, the drain region 13 and the drain electrode 14 are formed in the region close to the rear surface of the semiconductor substrate. The gate electrode 9 is embedded in the trench 7 via the gate insulative film (not depicted).

A part of the lower end of the source region 2 protrudes in the X direction and is adjacent to the trench 7 in the Y direction. The n-type semiconductor region 3 is formed to extend from the main surface of the semiconductor substrate 1 to a predetermined depth. The n-type semiconductor region 3 is adjacent to the trench 7 in the Y direction and is formed immediately above the p-type semiconductor region 4a in the X direction. The n-type semiconductor region 3 is formed immediately above the lower end of the source region 2 protruding in the X direction, via the p-type semiconductor region 4a. The n-type semiconductor region 3 separates from the source region 2 via the p-type semiconductor region 4a in the X direction. The n-type semiconductor region 3 is formed immediately above the semiconductor substrate 1 between the adjacent p-type semiconductor regions 4a in the X direction.

When the trench MOSFET according to this modification example is conducted, electrons supplied from the source wiring 11 flow toward the drain region 13 and the drain electrode 14 sequentially via the source region 2, the p-type semiconductor region 4a, the n-type semiconductor region 3, and the semiconductor substrate 1 as depicted with an arrow in FIG. 24. The channel is formed in the p-type semiconductor region 4a between the lower end of the source region 2 protruding in the X direction and the n-type semiconductor region 3 immediately above it. The n-type semiconductor region 3 is electrically connected to the drain region 13 and the drain electrode 14 via the semiconductor substrate 1. As a result, the drain (the n-type semiconductor region 3) is positioned closer to the main surface of the semiconductor substrate 1 than the channel.

The procedure of arranging the unit cells UR and UL and the X-end cell XL (generating the cell data) in steps S1 and S2 of FIG. 1 is similar to the steps described with reference to FIGS. 4 to 6. That is, first, the unit cells UR and UL are alternately arranged (step S1 of FIG. 1) as depicted in FIG. 24.

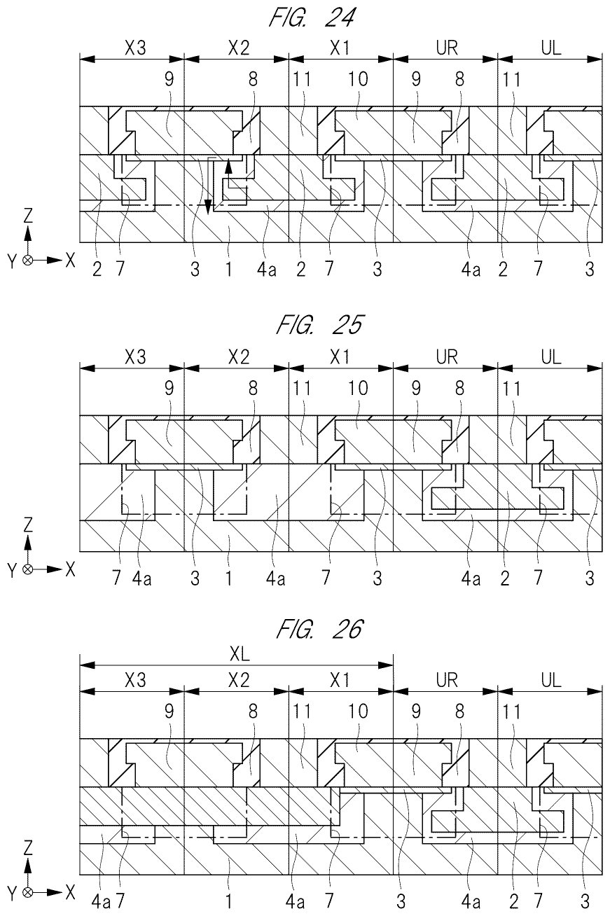

Next, as depicted in FIG. 25, the n-type semiconductor region which is electrically closer to the source than the channel (the p-type semiconductor region 4a) and is higher in impurity concentration than the p⁺-type semiconductor region 12 formed by a later-described step is removed from all of the first cell X1, the second cell X2, and the third cell X3. That is, the source region 2 is eliminated from the cell data of the first cell X1, the second cell X2, and the third cell X3. In other words, the design for forming the source region 2 in the first cell X1, the second cell X2, and the third cell X3 is cancelled.

Next, as depicted in FIG. 26, the p⁺-type semiconductor region 12 is arranged to totally cover the semiconductor substrate 1 sandwiched between the adjacent p-type semiconductor regions 4a at least in the end cell. As a result, the cell data of the X-end cell XL (XR) made of the first cell X1, the second cell X2, and the third cell X3 can be generated.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

It is needless to say that, for example, material, conductive type, manufacture condition and others of each component are not limited to those described in the embodiments, and may be variously modified. The semiconductor substrate and semiconductor films of the fixed conductive types have been described for the sake of explanation. However, the conductive types described in the embodiments are not limited. That is, although the n-type MOSFET has been described in the embodiments and the modification examples, even a p-type MOSFET in which the conductive types of semiconductor regions are inverted can provide similar effects to those of the embodiments and the modification examples.

What is claimed is:

1. A power semiconductor device comprising:
first unit cells and second unit cells which are cyclically arranged in a first direction and a second direction perpendicular to each other; and
a plurality of end cells,
wherein the first unit cell and the second unit cell are alternately arranged in the first direction,
the plurality of end cells include a first end cell, a second end cell, a third end cell, a fourth end cell, and a fifth end cell,
each number of arrangement cycles of the first unit cells and the second unit cells in the second direction change depending on repetition cycle coordinates of each of the first unit cell and the second unit cell in the first direction,
each of the first unit cells and the second unit cells which are cyclically arranged is adjacent to any of the plurality of end cells at an endmost portion of the cyclic arrangement in each of the first direction and the second direction, and
regions having the plurality of end cells are different in an electric property from the first unit cell and the second unit cell.

2. The power semiconductor device according to claim 1,
wherein each of the first unit cell and the second unit cell includes a MOSFET structure and a JFET region,
a drain of the MOSFET structure is connected to a source of the JFET region, and
the MOSFET structure in the regions having the plurality of end cells has a higher threshold voltage than threshold voltages of the first unit cell and the second unit cell.

3. The power semiconductor device according to claim 1,
wherein each of the first unit cell and the second unit cell includes a trench MOSFET structure and a JFET region,
a drain of the trench MOSFET structure is connected to a source of the JFET region, and
any of the plurality of end cells includes a trench not connected to the JFET region.

4. The power semiconductor device according to claim 1,
wherein the first end cell is adjacent to end portions of the first unit cells and the second unit cells which are cyclically arranged in the first direction,
the second end cell is adjacent to the end portion of the first unit cells which are cyclically arranged in the second direction, unless the second end cell overlaps the first end cell,
the third end cell is adjacent to the end portion of the second unit cells which are cyclically arranged in the second direction, unless the third end cell overlaps the first end cell,
the fourth end cell is adjacent to end portions of the second end cells and the third end cells which are cyclically arranged in the first direction, and
the fifth end cell is adjacent to the end portion of the first end cell in the second direction.

5. The power semiconductor device according to claim 1,
wherein each of the first unit cell, the second unit cell, and the first end cell has a MOSFET structure and a JFET region, and
the first end cell has a JFET width different from JFET widths of the first unit cell and the second unit cell or a channel length different from channel lengths of the first unit cell and the second unit cell.

6. The power semiconductor device according to claim 5,
wherein the first end cell has the JFET width narrower than JFET widths of the first unit cell and the second unit cell as getting closer to an end portion of the power semiconductor device in the first direction, or has the channel length longer than channel lengths of the first unit cell and the second unit cell as getting closer to the end portion of the power semiconductor device in the first direction.

7. The power semiconductor device according to claim 1,
wherein the second end cell, the third end cell, and the fourth end cell have an equivalent structure to the fifth end cell.

8. A power semiconductor device comprising:
a semiconductor substrate having a main surface and a rear surface opposite to the main surface;
unit cells which are cyclically arranged in a first direction along the main surface of the semiconductor substrate and a second direction perpendicular to the first direction in plan view; and
an end cell adjacent to an end portion of the plurality of unit cells arranged in the first direction or the second direction,
wherein the unit cell includes:
a guard region of a first conductive type formed in the semiconductor substrate;
a body region of the first conductive type formed in the semiconductor substrate;
a first semiconductor region of a second conductive type different from the first conductive type, formed in the semiconductor substrate;
a JFET region of the second conductive type formed in the semiconductor substrate between the guard regions adjacent in the first direction;
a source region of the second conductive type formed in the semiconductor substrate including the main surface of the semiconductor substrate and connected to the first semiconductor region;
a conductive connection portion formed on the main surface of the semiconductor substrate and connected to the source region;
a plurality of trenches which are formed in the main surface of the semiconductor substrate, each of which has an end portion in the first direction in the guard region, and which are repeatedly arranged in the second direction;
a fin made of the semiconductor substrate sandwiched between the trenches adjacent in the second direction; and
a gate electrode embedded in each of the plurality of trenches,
the first semiconductor region, the body region, and the JFET region are arranged in the semiconductor substrate adjacent to a side surface of the trench of the unit cell, sequentially from the main surface of the semiconductor substrate toward the rear surface of the semiconductor substrate, and
the end cell includes:
the guard region;
the body region;
a second semiconductor region of the first conductive type formed in the semiconductor substrate including the main surface of the semiconductor substrate;
the conductive connection portion connected to the second semiconductor region;
the trench;
the fin: and
the gate electrode.

9. A cell data generating system configured to execute:
generation of arrangement data for cyclically arranging first unit cells and second unit cells in a first direction and a second direction perpendicular to each other; and
generation of arrangement data of a plurality of end cells,
wherein the first unit cell and the second unit cell are alternately arranged in the first direction,
the plurality of end cells include a first end cell, a second end cell, a third end cell, a fourth end cell, and a fifth end cell,
each number of arrangement cycles of the first unit cells and the second unit cells in the second direction change depending on repetition cycle coordinates of each of the first unit cells and the second unit cells in the first direction,
each of the first unit cells and the second unit cells which are cyclically arranged is adjacent to any of the plurality of end cells at an endmost portion of the cyclic arrangement in each of the first direction and the second direction, and
regions having the plurality of end cells are different in an electric property from the first unit cell and the second unit cell.

10. The cell data generating system according to claim 9,
wherein each of the first unit cell and the second unit cell includes:
a guard region of a first conductive type formed in a semiconductor substrate having a main surface and a rear surface opposite to the main surface;
a body region of the first conductive type formed in the semiconductor substrate;
a first semiconductor region of a second conductive type different from the first conductive type, formed in the semiconductor substrate;
a JFET region of the second conductive type formed in the semiconductor substrate between the guard regions adjacent in the first direction;
a source region of the second conductive type formed in the semiconductor substrate including the main surface of the semiconductor substrate and connected to the first semiconductor region;
a conductive connection portion formed on the main surface of the semiconductor substrate and connected to the source region;
a plurality of trenches which are formed in the main surface of the semiconductor substrate, each of which has an end portion in the first direction in the guard region, and which are repeatedly arranged in the second direction;
a fin made of the semiconductor substrate sandwiched between the trenches adjacent in the second direction; and
a gate electrode embedded in each of the plurality of trenches,
the first semiconductor region, the body region, and the JFET region are arranged in the semiconductor substrate adjacent to a side surface of the trench of each of the first unit cell and the second unit cell, sequentially from the main surface of the semiconductor substrate toward the rear surface of the semiconductor substrate, and
the end cell includes:
the guard region;
the body region;
a second semiconductor region of the first conductive type formed in the semiconductor substrate including the main surface of the semiconductor substrate;
the conductive connection portion connected to the second semiconductor region;
the trench;
the fin: and
the gate electrode.

11. The cell data generating system according to claim 10,
wherein the source region has a first impurity concentration, and
when cell data of the first end cell is generated,
the first unit cell, the second unit cell and the first end cell are arranged, the first end cell being connected to end portions of the first unit cell and the second unit cell which are arranged in the first direction and including a MOSFET structure and the JFET region,
a semiconductor region of the second conductive type which is electrically closer to a source electrode than the MOSFET structure and which has an impurity concentration higher than the first impurity concentration is removed from the first end cell, and
the second semiconductor region having an impurity concentration higher than the first impurity concentration is arranged to overlap the MOSFET structure or the JFET region in plan view.

12. The cell data generating system according to claim 10,
wherein each of the first unit cell and the second unit cell includes a gate wiring which is formed on the main surface of the semiconductor substrate, which is connected to the gate electrode in each of the plurality of trenches arranged in the second direction, and which extends in the second direction, and,
when cell data of the second end cell and the third end cell is generated,
the second end cell is arranged at a position adjacent to the end portion of the first unit cells cyclically arranged in the second direction, unless the second end cell overlaps the first end cell,
the third end cell is arranged at a position adjacent to the end portion of the second unit cells cyclically arranged in the second direction, unless the third end cell overlaps the first end cell, and
as compared to a cell in which the first unit cell or the second unit cell is expanded or shrunk in the second direction, in each of the second end cell and the third end cell, components other than the gate wiring and the guard region are cancelled in the middle of the second direction, the JFET region is closed in the middle of the second direction, and the second semiconductor region is arranged in each of the entire second end cell and third end cell.

13. The cell data generating system according to claim 12,
wherein, when cell data of the fourth end cell is generated,
the fourth end cell is arranged at a position adjacent to an end portion of the first end cell in the second direction, at which the first end cell is not arranged adjacently in the first direction, and
as compared to a cell in which the first end cell is expanded or shrunk in the second direction, components other than the gate wiring and the guard region are cancelled in the middle of the second direction, the JFET region is closed in the middle of the second direction, and the second semiconductor region is arranged in the entire fourth end cell.

14. The cell data generating system according to claim 12,
wherein, when cell data of the fifth end cell is generated,
the fifth end cell is arranged at a position adjacent to an end portion of the first end cell in the second direction, at which the first end cell is arranged adjacently in the first direction, and
as compared to a cell in which the first end cell is expanded or shrunk in the second direction, components other than the gate wiring and the guard region are cancelled in the middle of the second direction, the JFET region is closed in the middle of the second direction, the second semiconductor region is arranged in the entire fifth end cell, and the guard region having a certain length from a region connected to the first unit cell is removed.

15. A power semiconductor device equivalent to a structure generated by the cell data generating system according to claim 9.
